(19) United States
(12) Patent Application Publication
(10) Pub. No.: US 2026/0157149 A1
(43) Pub. Date: Jun. 4, 2026

(54) WAFER PLACEMENT TABLE

(71) Applicant: NGK INSULATORS, LTD., Nagoya (JP)

(72) Inventors: Tatsuya KUNO, Nagoya-city (JP); Seiya INOUE, Handa-city (JP)

(21) Appl. No.: 19/463,440

(22) Filed: Jan. 29, 2026

Related U.S. Application Data
(63) Continuation of application No. PCT/JP2024/014923, filed on Apr. 15, 2024.

(51) Int. Cl. H10P 72/76; H01J 37/32

(52) U.S. Cl. CPC H10P 72/7624; H01J 37/3244; H01J 37/32651; H01J 37/32715

(57) ABSTRACT

A wafer placement table includes: a ceramic plate having a wafer placement surface on its upper surface; a gas passage provided to allow gas to pass in an up-down direction of the ceramic plate; a conductive base plate bonded to a lower surface of the ceramic plate and utilized as a plasma generating electrode; a gas supply path provided inside the base plate and communicating with the gas passage; and a shield member provided so as to surround the gas passage and electrically connected to the base plate.

### CROSS-REFERENCE TO RELATED APPLICATION

This application is a continuation application of International Application No. PCT/JP2024/014923, filed on Apr. 15, 2024, is incorporated herein by reference in its entirety.

### BACKGROUND OF THE INVENTION

### 1. Field of the Invention

The present invention relates to a wafer placement table.

### 2. Description of the Related Art

A wafer placement table has been conventionally used in a semiconductor manufacturing apparatus. For example, the wafer placement table in PTL 1 includes a ceramic plate having a wafer placement surface on its upper surface, a gas passage provided to allow gas to pass in an up-down direction of the ceramic plate, a conductive base plate bonded to a lower surface of the ceramic plate, a gas supply path provided inside the base plate. The gas passage consists of a porous plug placed in a through-hole formed in the ceramic plate. In the thus configured wafer placement table, a high-frequency voltage is applied between the base plate and an upper electrode provided above the wafer to generate plasma above the wafer, and the wafer is processed by the generated plasma. At this time, helium gas is introduced into the gas supply path from an external source. The helium gas is then supplied from the gas supply path through the gas passage to a lower side of the wafer. As a result, thermal conductivity between the wafer and the ceramic plate is improved. Since the helium gas passes through pores of the porous plug, it suppresses an occurrence of arc discharge on the lower side of the wafer compared with the case that the porous plug is absent. Without the porous plug, electrons generated by the ionization of helium are accelerated and collide with other helium atoms, thereby causing arc discharge. However, with the porous plug, the electrons strike the porous plug before colliding with other helium atoms, thereby suppressing arc discharge. When arc discharge occurs at the lower side of the wafer, the wafer is degraded and unusable as a device, which is undesirable.

### CITATION LIST

### Patent Literature

PTL 1: JP 2019-29384 A

### SUMMARY OF THE INVENTION

However, it is desirable to develop a new structure that suppresses discharge in the gas passage of the thus configured wafer placement table.

The present invention has been made to solve the above-described problem, and the main object is to provide a new structure that suppresses discharge in the gas passage.
[1] A wafer placement table of the present invention includes: a ceramic plate having a wafer placement surface on its upper surface; a gas passage provided to allow gas to pass in an up-down direction of the ceramic plate; a conductive base plate bonded to a lower surface of the ceramic plate and utilized as a plasma generating electrode; a gas supply path provided inside the base plate and communicating with the gas passage; and a shield member provided so as to surround the gas passage and electrically connected to the base plate.

In this wafer placement table, the shield member electrically connected to the conductive base plate, thereby suppressing the intrusion of equipotential lines into a lower portion of the gas passage during plasma generation. Therefore, it is easier to suppress discharge in the gas passage compared with the case where the shield member is not provided.

In this specification, up and down, left and right, and front and back, for example, are used to describe the present invention, but up and down, left and right, and front and back represent only a relative positional relationship. Thus, when the orientation of the wafer placement table is changed, up and down may become left and right, or left and right may become up and down. Such cases are also included in the technical scope of the present invention.
[2] In the wafer placement table of the present invention (wafer placement table described in [1] above), the shield member may be provided at least at a position close to the wafer placement surface. This facilitates further suppression of discharge in the gas passage. Note that “a position close to the wafer placement surface” refers to a position above one-half of the thickness of the ceramic plate as measured from the wafer placement surface.
[3] In the wafer placement table of the present invention (wafer placement table described in [1] or [2] above), the ceramic plate may have at least one electrode, the gas passage may be provided so as to pass through an electrode through-hole provided for each of the at least one electrode such that each of the at least one electrode is not exposed to an inner surface of the gas passage, and the shield member may be provided corresponding to each of the at least one electrode in a state electrically insulated from each of the at least one electrode. This also suppresses equipotential lines generated by the electrodes within the ceramic plate from intruding the gas passage.
[4] In the wafer placement table of the present invention (wafer placement table described in any one of [1] to [3] above), the ceramic plate may have a ceramic plate through-hole penetrating the ceramic plate in an up-down direction, and the gas passage may be provided in a plug disposed in the ceramic plate through-hole. This may facilitate forming the gas passage in some cases as compared with a case where the gas passage is provided directly in the ceramic plate itself.
[5] In the wafer placement table of the present invention (wafer placement table described in [4] above), the shield member may be embedded in the plug. This allows the shield member to be formed in the course of manufacturing the plug.
[6] In the wafer placement table of the present invention (wafer placement table described in any one of [1] to [4] above), the shield member may be embedded in the ceramic plate. This allows the shield member to be formed in the course of manufacturing the ceramic plate.
[7] The wafer placement table of the present invention (wafer placement table described in any one of [1] to [6] above), the gas passage may include a porous body allowing gas to pass in an up-down direction at least in an upper portion of the gas passage. Since equipotential lines intrude the upper portion of the gas passage, providing the porous body at least in the upper portion of the gas passage can suppress discharge occurring in the upper portion of the gas passage. The porous body may be provided only in the upper portion of the gas passage (the portion of the gas passage where equipotential lines intrude) or may be provided throughout the entire gas passage. In the former case, the gas flow rate can be increased compared to the latter.
[8] The wafer placement table of the present invention (wafer placement table described in any one of [1] to [6] above), the gas passage may have a spiral section or a zigzag section at least in an upper portion of the gas passage. Since equipotential lines intrude the upper portion of the gas passage, providing the spiral section or zigzag section at least in the upper portion of the gas passage can suppress discharge occurring in the upper portion of the gas passage. The spiral section or zigzag section may be provided only in the upper portion of the gas passage (the portion of the gas passage where equipotential lines intrude) or may be provided throughout the entire gas passage. In the former case, the gas flow rate can be increased compared to the latter. The vertical length of the spiral or zigzag section internally is preferably not more than a predetermined length (e.g., 0.5 mm, preferably 0.2 mm) to suppress discharge within this section.
[9] The wafer placement table of the present invention (wafer placement table described in any one of [1] to [8] above), the shield member may be a ring-shaped member whose central axis is perpendicular to the wafer placement surface. This facilitates shielding effect of the shield member. Note that “central axis is perpendicular to the wafer placement surface” includes not only cases where the central axis is perfectly perpendicular to the wafer placement surface, but also cases where the central axis is substantially perpendicular to the wafer placement surface (e.g., within allowable tolerances) (the same applies hereinafter).
[10] The wafer placement table of the present invention (wafer placement table described in any one of [1] to [8] above), the shield member may be a cylindrical member whose central axis is perpendicular to the wafer placement surface. This facilitates shielding effect of the shield member.
[11] The wafer placement table of the present invention (wafer placement table described in [10] above), the cylindrical member may have a flange portion at an upper end thereof. This suppresses excessive strengthening of the electric field intensity at an upper end of the cylindrical member.

### BRIEF DESCRIPTION OF THE DRAWINGS

FIG. 1 is a plan view of a wafer placement table 10.

FIG. 2 is a sectional view taken along line A-A of FIG. 1.

FIG. 3 is an enlarged partial view of FIG. 2.

FIG. 4 is an enlarged partial sectional view of a comparative embodiment.

FIGS. 5A to 5F are process diagrams illustrating the manufacturing steps of a ceramic plate 20.

FIG. 6 is an enlarged partial sectional view of another embodiment.

FIG. 7 is an enlarged partial sectional view of another embodiment.

FIG. 8 is an enlarged partial sectional view of another embodiment.

FIG. 9 is an enlarged partial sectional view of another embodiment.

FIG. 10 is an enlarged partial sectional view of another embodiment.

FIG. 11 is an enlarged partial sectional view of another embodiment.

FIG. 12 is an enlarged partial sectional view of another embodiment.

FIG. 13 is an enlarged partial sectional view of another embodiment.

### DETAILED DESCRIPTION OF THE INVENTION

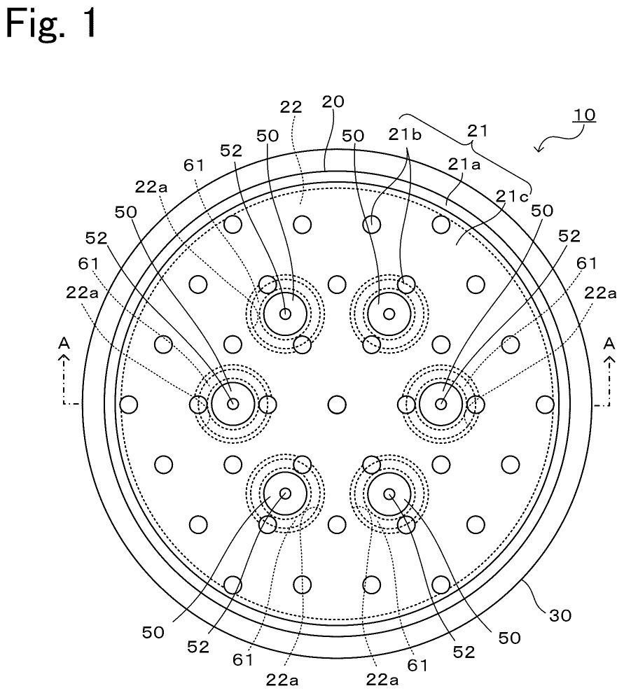

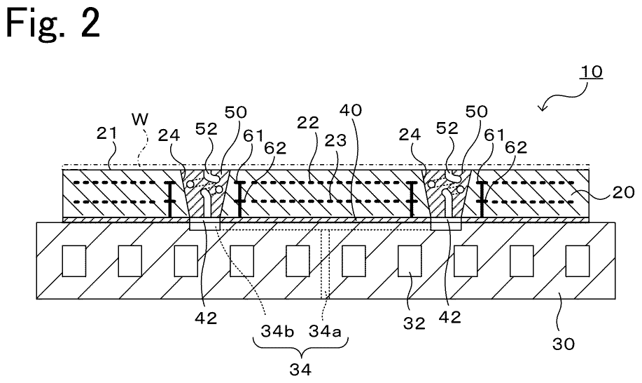

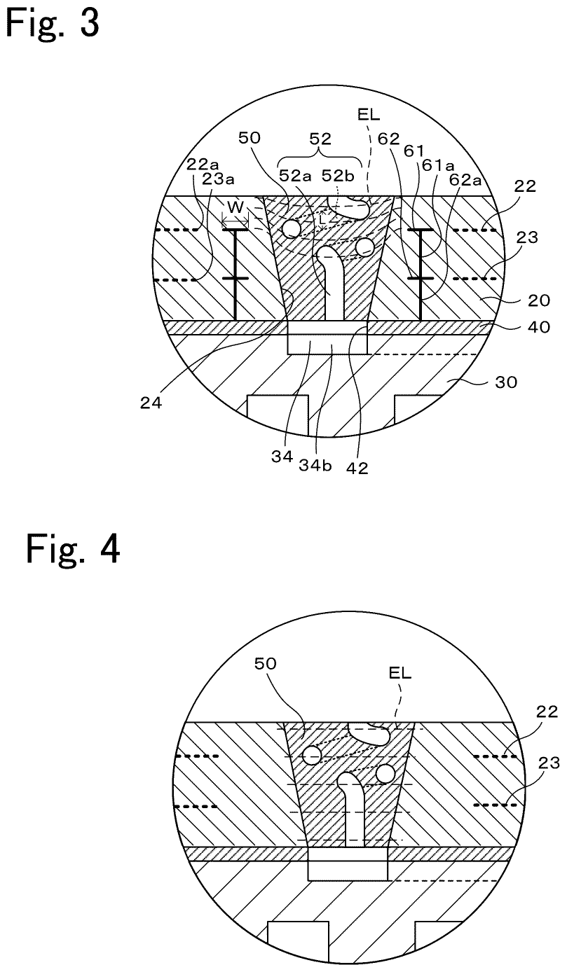

Preferred embodiments of the present invention will be described below with reference to the drawings. FIG. 1 is a plan view of a wafer placement table 10, FIG. 2 is a sectional view taken along line A-A of FIG. 1, and FIG. 3 is an enlarged partial view of FIG. 2. In FIGS. 2 and 3, for convenience, a seal band 21a, circular protrusions 21b, and a reference surface 21c of a wafer placement surface 21 are omitted.

The wafer placement table 10 includes a ceramic plate 20, a gas passage 52, a base plate 30, a metal bonding layer 40, and first and second shield members 61 and 62.

The ceramic plate 20 is a ceramic disk such as an alumina sintered body or an aluminum nitride sintered body (for example, having a diameter of 300 mm and a thickness of 5 mm). An upper surface of the ceramic plate 20 serves as a wafer placement surface 21. The ceramic plate 20 incorporates an electrostatic electrode 22 and a bias electrode 23. The electrostatic electrode 22 is disposed at a position close to the wafer placement surface 21 (for example, 0.3 to 0.6 mm from the wafer placement surface 21), while the bias electrode 23 is disposed at a position farther from the wafer placement surface 21. As shown in FIG. 1, the wafer placement surface 21 of the ceramic plate 20 is provided with a seal band 21a formed along an outer edge and a plurality of circular protrusions 21b formed over the entire surface. The seal band 21a and the circular protrusions 21b have the same height, which is, for example, several micrometers to several tens of micrometers. The electrostatic electrode 22 is, for example, a planar mesh electrode and is capable of being applied with a DC voltage. When a DC voltage is applied to the electrostatic electrode 22, a wafer W is attracted and held on the wafer placement surface 21 (specifically, on the upper surfaces of the seal band 21a and the circular protrusions 21b) by electrostatic attraction. When the application of the DC voltage is terminated, the electrostatic attraction holding the wafer W on the wafer placement surface 21 is released. A portion of the wafer placement surface 21 where neither the seal band 21a nor the circular protrusions 21b are provided is referred to as a reference surface 21c. The bias electrode 23 is, for example, a planar mesh electrode and is applied with a bias high-frequency voltage for drawing ions into the wafer W. The bias electrode 23 is a type of plasma generating electrode (RF electrode).

The gas passage 52 is a passage through which gas can pass in the up-down direction of the ceramic plate 20. Here, the gas passage 52 is provided inside a plug 50 fixed in a plug placement hole 24. The plug placement hole 24 penetrates through the ceramic plate 20 in the up-down direction and is formed so as to communicate with a gas supply path 34 of the base plate 30. The plug placement hole 24 penetrates the electrostatic electrode 22 and the bias electrode 23 in the up-down direction, but the electrostatic electrode 22 and the bias electrode 23 do not expose an inner peripheral surface of the plug placement hole 24. The plug placement hole 24 is a tapered hole having an inverted truncated cone space with an upper opening area larger than a lower opening area. In plan view, a plurality of plug placement holes 24 are provided at multiple positions of the ceramic plate 20 (for example, at multiple positions arranged at equal intervals along the circumferential direction). The plug 50 is a dense ceramic of inverted truncated cone shape (for example, the same material as the ceramic plate 20) disposed in the plug placement hole 24. The plug 50 is provided with a gas passage 52 extending from a lower surface to an upper surface of the plug 50. The gas passage 52 has a linear portion 52a extending vertically at a lower portion of the gas passage 52 and a spiral portion 52b at an upper portion of the gas passage 52. The spiral portion 52b is formed from an upper end of the gas passage 52 to at least a position where equipotential lines EL (see FIG. 3) intrude. A vertical length L (see FIG. 3) in the spiral portion 52 b is preferably set to 0.5 mm or less, more preferably 0.2 mm or less, in order to suppress arc discharge. Arc discharge occurs when electrons generated due to ionization of gas (for example, helium gas) inside the gas passage 52 are accelerated in the direction of electric field lines (perpendicular to the equipotential line EL) and collide with other helium atoms. However, when the vertical length of the gas passage 52 is 0.5 mm or less (more preferably 0.2 mm or less), such arc discharge can be suppressed. Considering that a sufficient gas flow rate should be ensured, the vertical length of the spiral portion 52b is preferably made as long as possible within a range in which arc discharge does not occur (for example, 0.1 mm or more).

The base plate 30 is a conductive disk having high thermal conductivity (a disk having a diameter equal to or larger than that of the ceramic plate 20). Inside the base plate 30, a refrigerant flow path 32 through which a refrigerant (for example, an electrically insulating liquid such as a fluorine-based inert liquid) circulates and a gas supply path 34 for supplying gas to the gas passage 52 are formed. The refrigerant flow path 32 is formed in a manner of a one-stroke pattern from an inlet to an outlet over the entire surface of the base plate 30 in plan view. Examples of the material of the base plate 30 include metals and composite materials. Examples of the metals include Mo. Examples of the composite materials include a metal-ceramic composite material. Examples of the metal-ceramic composite material include metal matrix composite materials (MMCs) and ceramic matrix composite materials (CMCs). Specific examples of these composite materials include materials containing Si, SiC, and Ti, and materials prepared by impregnating SiC porous bodies with Al and/or Si. The material containing Si, SiC, and Ti is referred to as SiSiCTi. The material prepared by impregnating a SiC porous body with Al is referred to as AlSiC, and the material prepared by impregnating a SiC porous body with Si is referred to as SiSiC. The material of the base plate 30 is preferably a material having a coefficient of thermal expansion close to that of the material of the ceramic plate 20. The base plate 30 is used as a source electrode (a type of plasma generating electrode (RF electrode)) to which a source high-frequency voltage for generating plasma is applied. For example, the bias high-frequency voltage is several hundred kHz, and the source high-frequency voltage is several tens of MHz to several hundreds of MHz.

The gas supply path 34 comprises a ring portion 34b concentric with the base plate 30 in plan view and an introduction portion 34a for introducing gas from a lower surface of the base plate 30 into the ring portion 34b. The ring portion 34b communicates with the gas passage 52 through a through-hole 42 of the metal bonding layer 40. The introduction portion 34a may be provided as, for example, a single line. Gas introduced into the introduction portion 34a is distributed to each gas passage 52 through the ring portion 34b.

The metal bonding layer 40 bonds the lower surface of the ceramic plate 20 and the upper surface of the base plate 30 to each other. The metal joint layer 40 is formed, for example, by TCB (thermal compression bonding). The TCB is a well-known method in which a metallic joint member is held between two members to be joined together and the two members are heated to a temperature equal to or lower than the solidus temperature of the metallic joint member to pressure-bond the two members together. The metal bonding layer 40 may be a layer formed of solder or a metal brazing material. The metal bonding layer 40 has a through hole 42. The through-hole 42 is provided at a position for communicating the gas passage 52 with the gas supply path 34.

The first and second shield members 61 and 62 are ring-shaped members having central axes perpendicular to the wafer placement surface 21 and are provided so as to surround the gas passage 52 (here, so as to surround the plug 50). A ring width W (FIG. 3) is larger than diameters of first and second vias 61a and 62a. The first shield member 61 is provided so as to correspond to the electrostatic electrode 22 and to be at the same height as the electrostatic electrode 22. The second shield member 62 is provided so as to correspond to the bias electrode 23 and to be at the same height as the bias electrode 23. In other words, the first shield member 61 is disposed at a position close to the wafer placement surface 21, and the second shield member 62 is provided in part of the region from the position of the first shield member 61 (close to the wafer placement surface 21) to the lower surface of the ceramic plate 20. The electrostatic electrode 22 has an electrostatic electrode through-hole 22a at a position facing the plug 50. The bias electrode 23 has a bias electrode through-hole 23a at a position facing the plug 50. The first shield member 61 is embedded in the ceramic plate 20 inside the electrostatic electrode through-hole 22a in a state electrically insulated from the electrostatic electrode 22. The second shield member 62 is embedded in the ceramic plate 20 inside the bias electrode through-hole 23a in a state electrically insulated from the bias electrode 23. The first shield member 61 and the second shield member 62 are electrically connected by the first via 61a extending in the up-down direction, and the second shield member 62 and the metal bonding layer 40 are electrically connected by the second via 62a extending in the up-down direction. At least one first via 61a suffices, and at least one second via 62a also suffices. Since the metal bonding layer 40 is electrically connected to the base plate 30, the first and second shield members 61 and 62 are also electrically connected to the base plate 30. Therefore, the first and second shield members 61 and 62 become equal in potential to the base plate 30.

Next, an example of use of the wafer placement table 10 configured as above will be described. First, with the wafer placement table 10 installed in a chamber (not shown), a wafer W is placed on the wafer placement surface 21. The interior of the chamber is then evacuated by a vacuum pump to adjust it to a predetermined degree of vacuum, and a DC voltage is applied to the electrostatic electrode 22 of the ceramic plate 20 to generate electrostatic attraction, thereby attracting and fixing the wafer W onto the wafer placement surface 21 (specifically, onto the upper surfaces of the seal band 21a and the circular protrusions 21b). Next, the inside of the chamber is set to a reactive gas atmosphere having a predetermined pressure (for example, several tens to several hundreds of Pa). In this state, a source high-frequency voltage is applied between an upper electrode (not shown) provided at a ceiling portion of the chamber and the base plate 30, and a bias high-frequency voltage is applied between the upper electrode and the bias electrode 23, thereby generating plasma. A surface of the wafer W is processed by the generated plasma. A refrigerant is circulated through the refrigerant flow path 32 of the base plate 30. A backside gas is introduced into the gas supply path 34 from a gas cylinder (not shown). As the backside gas, a heat transfer gas (for example, helium) is used. The backside gas is supplied and enclosed in a space between a rear surface of the wafer W and the reference surface 21c of the wafer placement surface 21 via the gas supply path 34, the through-hole 42, and the gas passage 52. Owing to the presence of this backside gas, heat conduction between the wafer W and the ceramic plate 20 is efficiently performed.

In the wafer placement table 10, by virtue of providing first and second shield members 61 and 62 that are electrically connected to the conductive base plate 30, intrusion of an equipotential line EL into the lower portion of the gas passage 52 (a position distant from the wafer placement surface 21) during plasma generation can be suppressed. Therefore, as compared with the case where the first and second shield members 61 and 62 are not provided, discharge in the gas passage 52 is more easily suppressed. An example of the equipotential line EL in the present embodiment is shown in FIG. 3, and an example of the equipotential line EL in a case (comparative embodiment) where the first and second shield members 61 and 62 are not provided is shown in FIG. 4. In the comparative embodiment, as shown in FIG. 4, equipotential lines EL extending in the horizontal direction exist over the entire vertical extent of the gas passage 52. In contrast, in the present embodiment, as shown in FIG. 3, although the equipotential line EL curves and intrudes into the upper portion of the gas passage 52, intrusion of the equipotential line EL into the lower portion of the gas passage 52 is suppressed. Accordingly, in the present embodiment, even when the lower portion of the gas passage 52 is the straight portion 52a extending in the up-down direction, discharge in the straight portion 52a can be suppressed.

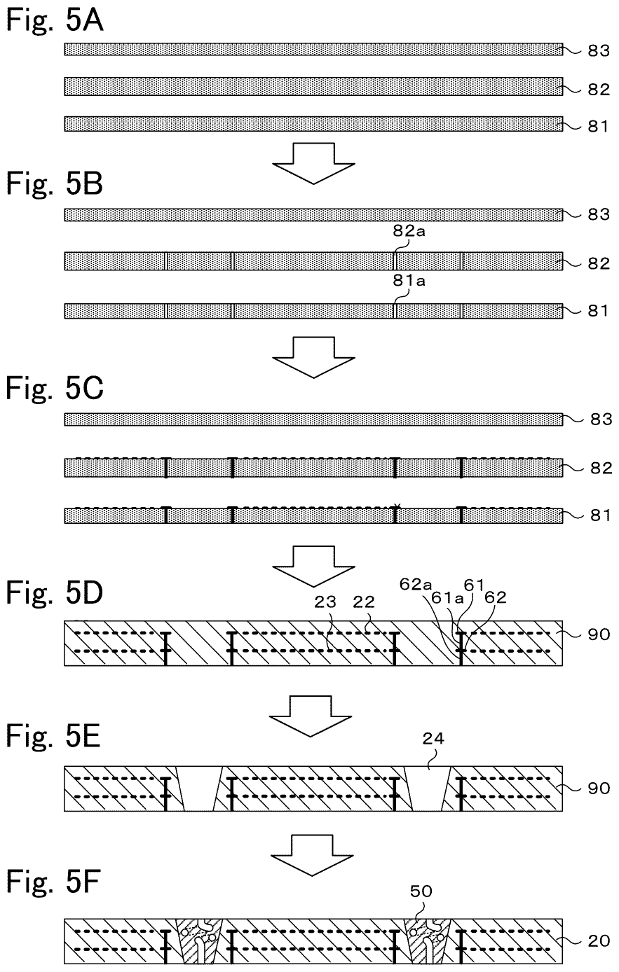

Next, a manufacturing example of the wafer placement table 10 will be described. Since the base plate 30 can be manufactured by a known method, a manufacturing example of the ceramic plate 20 will be described here. FIGS. 5A to 5F are process diagrams illustrating manufacturing steps of the ceramic plate 20. First, three ceramic green sheets 81, 82, and 83 are prepared that substantially match shapes obtained by horizontally cutting the ceramic plate 20 at the plane of the electrostatic electrode 22 and at the plane of the bias electrode 23 (FIG. 5A). Then, a hole 81a penetrating in the up-down direction is provided at a position of the second via 62a in a first ceramic green sheet 81, and a hole 82a penetrating in the up-down direction is provided at a position of the first via 61a in a second ceramic green sheet 82 (FIG. 5B). A pattern having the same shape as the electrostatic electrode 22 and the first shield member 61 is then printed with a conductive paste on an upper surface of the first ceramic green sheet 81, and the hole 81a is filled with the conductive paste. Further, a pattern having the same shape as the bias electrode 23 and the second shield member 62 is printed with a conductive paste on an upper surface of the second ceramic green sheet 82, and the hole 82a is filled with the conductive paste (FIG. 5C). Thereafter, the second ceramic green sheet 82 is laminated on the first ceramic green sheet 81, and a third ceramic green sheet 83 is further laminated thereon to obtain a laminate body, and the laminate body is hot-press fired to obtain a ceramic sintered body 90 (FIG. 5D). In the ceramic sintered body 90, in addition to the electrostatic electrode 22 and the bias electrode 23, the first and second shield members 61 and 62 and the first and second vias 61a and 62b are formed. In this ceramic sintered body 90, the plug placement hole 24 is formed (FIG. 5E). Thereafter, by placing a separately prepared plug 50 in the plug placement hole 24 and fixing it with an adhesive, the ceramic plate 20 is obtained (FIG. 5F).

In the wafer placement table 10 described in detail above, by virtue of providing first and second shield members 61 and 62 that are electrically connected to the conductive base plate 30, intrusion of equipotential lines EL into the lower portion of the gas passage 52 (a position distant from the wafer placement surface 21) during plasma generation can be suppressed. Therefore, as compared with the case where the first and second shield members 61 and 62 are not provided, discharge in the gas passage 52 is more easily suppressed. As a result, the degree of freedom in designing the lower portion of the gas passage 52 increases. For example, as in the wafer placement table 10 described above, measures against discharge at the lower portion of the gas passage 52 (e.g., making it spiral) can be omitted, and the lower portion can be formed as the straight portion 52a.

Further, the ceramic plate 20 includes the electrostatic electrode 22 and the bias electrode 23. The gas passage 52 passes through the electrostatic electrode through-hole 22a such that the electrostatic electrode 22 is not exposed to an inner surface of the gas passage 52, and passes through the bias electrode through-hole 23a such that the bias electrode 23 is not exposed to the inner surface of the gas passage 52. The first shield member 61 is provided so as to correspond to the electrostatic electrode 22 in a state electrically insulated from the electrostatic electrode 22, and the second shield member 62 is provided so as to correspond to the bias electrode 23 in a state electrically insulated from the bias electrode 23. Therefore, intrusion into the gas passage 52 of equipotential lines generated by the electrostatic electrode 22 and the bias electrode 23 within the ceramic plate 20 can also be suppressed.

Furthermore, the ceramic plate 20 has the plug placement hole 24 (a ceramic plate through-hole) that penetrates the ceramic plate 20 in the up-down direction, and the gas passage 52 is provided in the plug 50 disposed in the plug placement hole 24. Accordingly, as compared with a case where the gas passage 52 is provided directly in the ceramic plate 20 itself, formation of the gas passage 52 can in some cases be facilitated.

Still further, the first and second shield members 61 and 62 are embedded in the ceramic plate 20. Therefore, as shown in FIGS. 5A to 5F, the first and second shield members 61 and 62 can be formed in the course of manufacturing the ceramic plate 20.

Moreover, the gas passage 52 has the straight portion 52a at the lower portion of the gas passage 52 and the spiral portion 52b at the upper portion thereof. As shown in FIG. 3, the equipotential lines EL intrude into the upper portion of the gas passage 52. Accordingly, by providing the spiral portion 52b at the upper portion of the gas passage 52, occurrence of discharge in the upper portion of the gas passage 52 can be suppressed.

Furthermore, the first and second shield members 61 and 62 are ring-shaped members whose central axes are perpendicular to the wafer placement surface 21. Therefore, the first and second shield members 61 and 62 readily exhibit a shielding effect.

It goes without saying that the present invention is not limited to the embodiment described above, and may be implemented in various modes insofar as it falls within the technical scope of the invention.

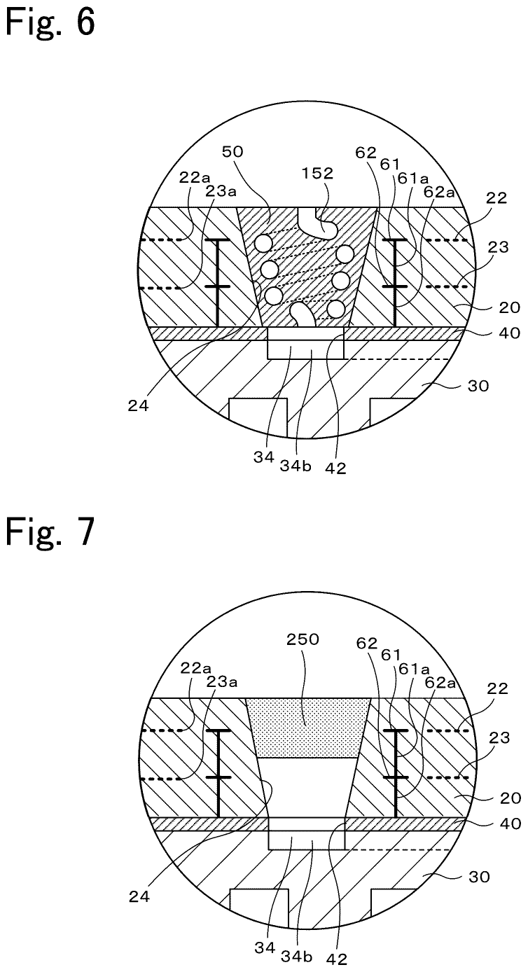

In the embodiment described above, as the gas passage 52, one having the straight portion 52a at the lower portion and the spiral portion 52b at the upper portion was adopted; however, a gas passage 152 shown in FIG. 6 may be adopted instead of the gas passage 52. In FIG. 6, components identical to those of the embodiment described above are denoted by the same reference numerals. The gas passage 152 is a spiral passage extending from the lower surface to the upper surface of the plug 50. Even in this case, effects similar to those of the embodiment described above can be obtained. However, since the gas passage 52 has fewer spiral portions than the gas passage 152, gas flows more easily and the gas flow rate can be increased. Therefore, when the gas passage 52 is adopted, the number thereof can be reduced as compared with the case where the gas passage 152 is adopted. This reduces manufacturing cost. In addition, although the gas passage 52 constitutes a temperature singular point on the wafer W, by reducing the number thereof, temperature singular points decrease and temperature uniformity improves. Note that the spiral portion 52b of the gas passage 52 may be configured as a zigzag portion, and the spiral passage of the gas passage 152 may also be configured as a zigzag passage.

In the embodiment described above, the dense plug 50 having the internal gas passage 52 was adopted; however, a plug 250 shown in FIG. 7 may be adopted instead of the plug 50. In FIG. 7, components identical to those of the embodiment described above are denoted by the same reference numerals. The plug 250 is a plug made of a porous body (porous plug). The plug 250 is provided in the upper portion of the plug placement hole 24 (for example, in a section from an upper end of the plug placement hole 24 to a position into which the equipotential line EL intrudes). Gas can pass in the up-down direction through micropores of the porous body of the plug 250. Thus, the micropores of the porous body serve as a gas passage. Even in this case, effects similar to those of the embodiment described above can be obtained. The plug 250 may be provided over the entirety of the plug placement hole 24. However, when the plug 250 is provided only in the upper portion of the plug placement hole 24, gas flows more easily than in the case where it is provided over the entirety, so that the gas flow rate can be increased; as a result, the number of plugs 250 can be reduced. This reduces manufacturing cost. In addition, although the plug 250 constitutes a temperature singular point on the wafer W, by reducing the number thereof, temperature singular points decrease and temperature uniformity improves.

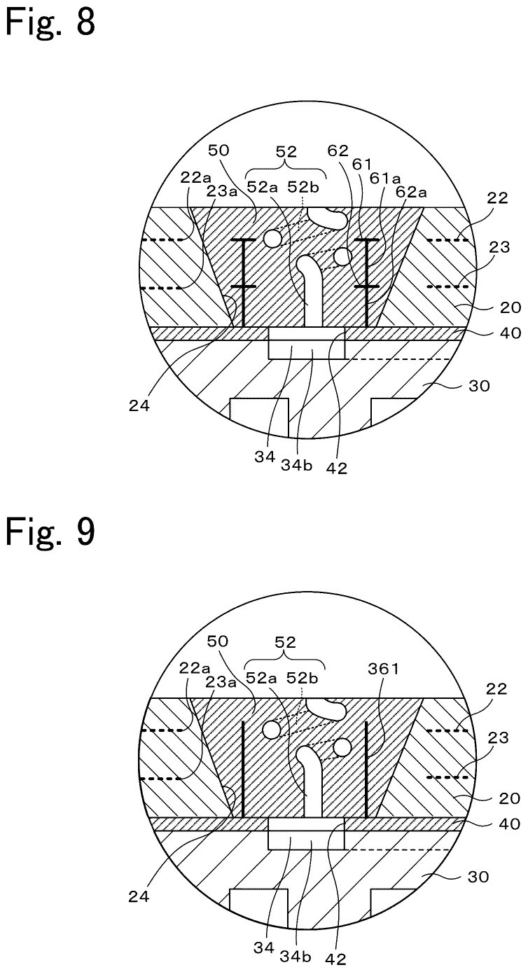

In the embodiment described above, the first and second shield members 61 and 62 and the first and second vias 61a and 62b are embedded in the ceramic plate 20; however, as shown in FIG. 8, these may be embedded in the plug 50. In this case, the first and second shield members 61 and 62 and the first and second vias 61a and 62b can be formed in the course of manufacturing the plug 50. Such a plug 50 can be manufactured, for example, by using a 3D printer.

In FIG. 8, the first and second shield members 61 and 62 and the first and second vias 61a and 62b are embedded in the plug 50; however, instead of these, a shield member 361 shown in FIG. 9 may be adopted. The shield member 361 is a cylindrical member whose central axis is perpendicular to the wafer placement surface 21. A lower end of the shield member 361 is electrically connected to the metal bonding layer 40. Therefore, the shield member 361 is electrically connected to the base plate 30 via the metal bonding layer 40. An upper end of the shield member 361 is disposed at a position close to the wafer placement surface 21 (here, at the same position as the electrostatic electrode 22). In other words, the shield member 361 is provided in the entirety of a region from a position close to the wafer placement surface 21 to a lower surface of the ceramic plate 20. In this case, the entirety of the shield member 361 becomes equal in potential to the base plate 30. Since the shield member 361 is a cylindrical member, it readily exhibits a shielding effect. Such a cylindrical shield member 361 may be embedded in the ceramic plate 20 rather than in the plug 50, but it is easier to manufacture when embedded in the plug 50. The plug 50 of FIG. 9 can be manufactured, for example, by using a 3D printer.

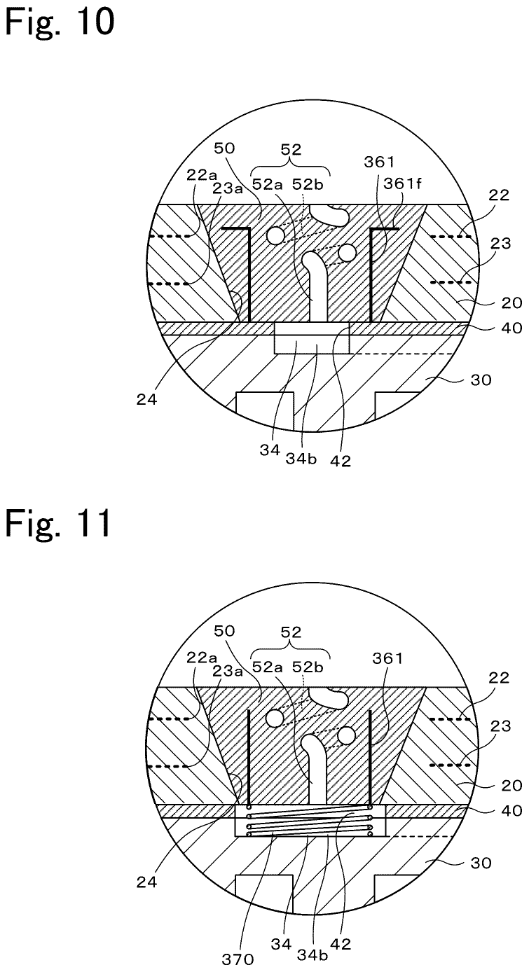

In FIG. 9, the cylindrical shield member 361 is embedded in the plug 50; however, as shown in FIG. 10, an outward flange portion 361f may be provided at an upper end of the shield member 361. In this case, the entirety of the shield member 361 including the flange portion 361f becomes equal in potential to the base plate 30. Thus, it is possible to suppress excessive strengthening of the electric field intensity at the upper end of the cylindrical shield member 361.

In FIG. 9, the cylindrical shield member 361 is electrically connected to the base plate 30 via the metal bonding layer 40; however, as shown in FIG. 11, the shield member 361 may be electrically connected to the base plate 30 via a metal spring 370. The metal spring 370 is disposed in the gas supply path 34 and the through-hole 42 of the metal bonding layer 40. The metal spring 370 is disposed in a compressed state between a lower end of the shield member 361 and a bottom surface of the gas supply path 34 (ring portion 34b) of the base plate 30. Although the metal spring 370 is illustrated in FIG. 11, the present invention is not particularly limited to the metal spring 370 as long as a conductive elastic member that permits passage of gas in the up-down direction is used. For example, a metal mesh that is extendable and contractible in the up-down direction or a mass of metal fibers may be used. Such a structure is particularly useful when a resin adhesive layer is used in place of the metal bonding layer 40.

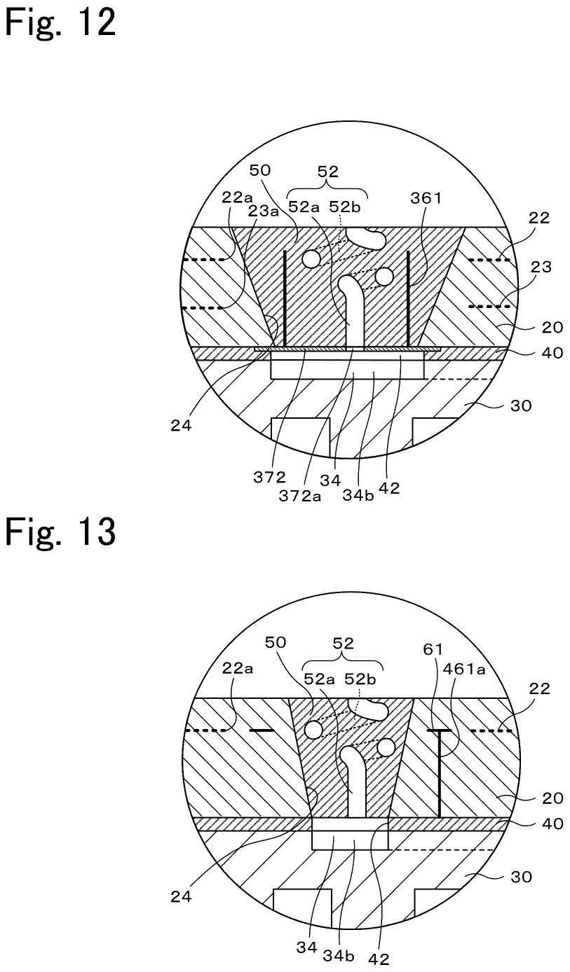

Instead of the metal spring 370 in FIG. 11, a conductive film 372 that covers a lower surface of the plug 50 and also covers a part of a lower surface of the ceramic plate 20 (periphery of the plug placement hole 24) may be provided as shown in FIG. 12. In FIG. 12, components identical to those of the embodiment described above are denoted by the same reference numerals. The conductive film 372 is formed by, for example, sputtering. A through-hole 372a is provided in the conductive film 372 at a position facing the gas passage 52. Therefore, the conductive film 372 maintains communication between the gas supply path 34 and the gas passage 52. The shield member 361 is electrically connected to the base plate 30 via the conductive film 372 and the metal bonding layer 40.

In the embodiment described above, the electrostatic electrode 22 and the bias electrode 23 are embedded in the ceramic plate 20; however, at least one of the electrostatic electrode 22, the bias electrode 23, and a heater electrode capable of heating the wafer W may be embedded in the ceramic plate 20. Alternatively, these electrodes need not be embedded in the ceramic plate 20. For example, in a case where only the electrostatic electrode 22 is embedded in the ceramic plate 20, as shown in FIG. 13, the first shield member 61 may be retained and the second shield member 62 may be omitted, and the first shield member 61 may be electrically connected to the base plate 30 via an internal via 461a of the ceramic plate 20. Even in a case where no electrode is embedded in the ceramic plate 20, similarly to FIG. 13, the first shield member 61 may be retained and the second shield member 62 may be omitted, and the first shield member 61 may be electrically connected to the base plate 30 via the internal via 461a of the ceramic plate 20. Although discharge suppression effect can be obtained with at least one shield member, provision of a plurality of shield members enables discharge to be suppressed more effectively. Further, the shield members need not be provided at the same heights as the respective electrodes (the electrostatic electrode 22 and the bias electrode 23), and may be provided at different heights.

In the embodiment described above, the first shield member 61 is provided at a position close to the wafer placement surface 21 (a position above one-half of the thickness of the ceramic plate 20 as measured from the wafer placement surface 21), but the invention is not limited thereto. For example, a position at which the first shield member 61 is provided may be arbitrary. However, from the viewpoint of suppressing discharge in the gas passage, it is preferable to provide the first shield member 61 at a position above two-thirds of the thickness of the ceramic plate 20 as measured from the wafer placement surface 21, and more preferably at a position above one-half of the thickness.

In the embodiment described above, the ceramic plate 20 and the base plate 30 are bonded by the metal bonding layer 40; however, a resin adhesive layer may be used in place of the metal bonding layer 40. In that case, electrical connection between the second via 62a and the base plate 30 may be achieved by using the metal spring 370 shown in FIG. 11, or by using a conductive wire that penetrates the resin adhesive layer in the up-down direction.

In the embodiment described above, as the gas supply path 34, one including the introduction portion 34a and the ring portion 34b was exemplified, but the invention is not limited thereto. For example, as the gas supply path, a base plate through-hole that penetrates the base plate 30 in the up-down direction and communicates with the gas passage 52 may be adopted.

In the embodiment described above, an internal space of the plug placement hole 24 is an inverted truncated cone space, but it may be a cylindrical space. In that case, the plug 50 is also formed in a cylindrical shape.

In the embodiment described above, the plug 50 is disposed in the plug placement hole 24; however, the plug 50 need not be disposed in the plug placement hole 24. In that case, the plug placement hole 24 serves as the gas passage.

What is claimed is:

1. A wafer placement table comprising:
a ceramic plate having a wafer placement surface on its upper surface;
a gas passage provided to allow gas to pass in an up-down direction of the ceramic plate;
a conductive base plate bonded to a lower surface of the ceramic plate and utilized as a plasma generating electrode;
a gas supply path provided inside the base plate and communicating with the gas passage; and
a shield member provided so as to surround the gas passage and electrically connected to the base plate,
wherein the ceramic plate has a ceramic plate through-hole penetrating the ceramic plate in an up-down direction, and
the gas passage is provided in a plug disposed in the ceramic plate through-hole;
the shield member is embedded in the plug.

2. A wafer placement table comprising:
a ceramic plate having a wafer placement surface on its upper surface;
a gas passage provided to allow gas to pass in an up-down direction of the ceramic plate;
a conductive base plate bonded to a lower surface of the ceramic plate and utilized as a plasma generating electrode;
a gas supply path provided inside the base plate and communicating with the gas passage; and
a shield member provided so as to surround the gas passage and electrically connected to the base plate,
wherein the shield member is a ring-shaped member whose central axis is perpendicular to the wafer placement surface.

3. A wafer placement table comprising:
a ceramic plate having a wafer placement surface on its upper surface;
a gas passage provided to allow gas to pass in an up-down direction of the ceramic plate;
a conductive base plate bonded to a lower surface of the ceramic plate and utilized as a plasma generating electrode;
a gas supply path provided inside the base plate and communicating with the gas passage; and
a shield member provided so as to surround the gas passage and electrically connected to the base plate,
wherein the shield member is a cylindrical member whose central axis is perpendicular to the wafer placement surface and the cylindrical member has a flange portion at an upper end thereof.

4. The wafer placement table according to claim 1,
wherein the shield member is provided at least at a position close to the wafer placement surface.

5. The wafer placement table according to claim 1,
wherein the ceramic plate has at least one electrode,
the gas passage is provided so as to pass through an electrode through-hole provided for each of the at least one electrode such that each of the at least one electrode is not exposed to an inner surface of the gas passage, and
the shield member is provided corresponding to each of the at least one electrode in a state electrically insulated from each of the at least one electrode.

6. The wafer placement table according to claim 1,
wherein the gas passage includes a porous body allowing gas to pass in an up-down direction at least in an upper portion of the gas passage.

7. The wafer placement table according to claim 1,
wherein the gas passage has a spiral section or a zigzag section at least in an upper portion of the gas passage.

8. The wafer placement table according to claim 1,
wherein the shield member is a cylindrical member whose central axis is perpendicular to the wafer placement surface.

9. The wafer placement table according to claim 2,
wherein the shield member is provided at least at a position close to the wafer placement surface.

10. The wafer placement table according to claim 2,
wherein the ceramic plate has at least one electrode,
the gas passage is provided so as to pass through an electrode through-hole provided for each of the at least one electrode such that each of the at least one electrode is not exposed to an inner surface of the gas passage, and
the shield member is provided corresponding to each of the at least one electrode in a state electrically insulated from each of the at least one electrode.

11. The wafer placement table according to claim 2,
wherein the ceramic plate has a ceramic plate through-hole penetrating the ceramic plate in an up-down direction, and
the gas passage is provided in a plug disposed in the ceramic plate through-hole.

12. The wafer placement table according to claim 11,
wherein the shield member is embedded in the plug.

13. The wafer placement table according to claim 2,
wherein the shield member is embedded in the ceramic plate.

14. The wafer placement table according to claim 2,
wherein the gas passage includes a porous body allowing gas to pass in an up-down direction at least in an upper portion of the gas passage.

15. The wafer placement table according to claim 3,
wherein the shield member is provided at least at a position close to the wafer placement surface.

16. The wafer placement table according to claim 3,
wherein the ceramic plate has at least one electrode,
the gas passage is provided so as to pass through an electrode through-hole provided for each of the at least one electrode such that each of the at least one electrode is not exposed to an inner surface of the gas passage, and
the shield member is provided corresponding to each of the at least one electrode in a state electrically insulated from each of the at least one electrode.

17. The wafer placement table according to claim 3,
wherein the ceramic plate has a ceramic plate through-hole penetrating the ceramic plate in an up-down direction, and
the gas passage is provided in a plug disposed in the ceramic plate through-hole.

18. The wafer placement table according to claim 17,
wherein the shield member is embedded in the plug.

19. The wafer placement table according to claim 3,
wherein the shield member is embedded in the ceramic plate.

20. The wafer placement table according to claim 3,
wherein the gas passage includes a porous body allowing gas to pass in an up-down direction at least in an upper portion of the gas passage.
